(19) United States
(12) Patent Application Publication
(10) Pub. No.: US 2022/0285183 A1
(43) Pub. Date: Sep. 8, 2022

(54) SEMICONDUCTOR INTELLIGENT DETECTION SYSTEM, INTELLIGENT DETECTION METHOD AND STORAGE MEDIUM

(71) Applicant: CHANGXIN MEMORY TECHNOLOGIES, INC., Hefei City (CN)

(72) Inventors: Ya MENG, Hefei City (CN); Ming-Hung HSIEH, Hefei City (CN); Sheng-Hua SU, Hefei City (CN)

(21) Appl. No.: 17/502,269

(22) Filed: Oct. 15, 2021

Related U.S. Application Data
(63) Continuation of application No. PCT/CN2021/109512, filed on Jul. 30, 2021.

(30) Foreign Application Priority Data
Mar. 4, 2021 (CN) 202110240270.X

(51) Int. Cl. H01L 21/67; G05B 19/418

(52) U.S. Cl. CPC H01L 21/67253; G05B 19/41865; G05B 2219/32365; G05B 2219/45031

(57) ABSTRACT

The present disclosure provides a semiconductor intelligent detection system, an intelligent detection method and a storage medium. The semiconductor intelligent detection system includes: a data import module, configured to acquire a data table to-be-detected; a data storage module, having a process resource database stored therein, a data type of data stored in the process resource database being used to perform data detection on items to-be-detected of a corresponding type; a resource detection module, connected to the data import module and the data storage module; wherein the resource detection module is configured to perform data detection on the items to-be-detected in the data table to-be-detected one by one, and record wrong items to-be-detected in an abnormity information table; and, an abnormity export module, connected to the resource detection module and configured to detect whether the resource detection module has detected the last item to-be-detected in the data table to-be-detected.

### CROSS-REFERENCE TO RELATED APPLICATIONS

This is a continuation of International Patent Application No. PCT/CN2021/109512, filed on Jul. 30, 2021, which claims the priority to Chinese Patent Application No. 202110240270.X titled “SEMICONDUCTOR INTELLIGENT DETECTION SYSTEM, INTELLIGENT DETECTION METHOD AND STORAGE MEDIUM” and filed on Mar. 4, 2021. The entire contents of International Patent Application No. PCT/CN2021/109512 and Chinese Patent Application No. 202110240270.X are incorporated herein by reference.

### TECHNICAL FIELD

The present disclosure relates to, but not limited to, a semiconductor intelligent detection system, an intelligent detection method and a storage medium.

### BACKGROUND

The semiconductor process resources (Flow resources) include a plurality of sub-items, such as equipment used in semiconductor production flows, process recipe and process yield information, and are used to instruct semiconductor process equipment to execute semiconductor process flows.

The settings of the semiconductor flows include: the flow applicant provides Flow resources to the flow setter, the flow setter examines the Flow resources until the Flow resources are correct and then inputted into the manufacturing specification manager (SM) system and sent to the material manager (MM) system for use.

However, it was found that Flow resource setting errors will affect the subsequent processing of a large number of wafers and thus have a fatal impact on the operation of the factory. However, since one complete Flow resource contains too many sub-items, the time consumption of manual detection is large, and the accuracy of resources cannot be ensured completely.

### SUMMARY

The following is the summary of the subject described in detail in the present disclosure. This summary is not intended to limit the protection scope defined by the claims.

The present disclosure provides a semiconductor intelligent detection system, an intelligent detection method and a storage medium.

A first aspect of the present disclosure provides a semiconductor intelligent detection system, comprising: a data import module, configured to acquire a data table to-be-detected, there being a plurality of items to-be-detected in the data table to-be-detected, the items to-be-detected comprising multiple types of semiconductor process resources; a data storage module, having a process resource database stored therein, a data type of data stored in the process resource database being used to perform data detection on items to-be-detected of a corresponding type; a resource detection module, connected to the data import module and the data storage module; wherein the resource detection module is configured to perform data detection on the items to-be-detected in the data table to-be-detected one by one based on the data type of the data stored in the process resource database, and record wrong items to-be-detected in an abnormity information table; and, an abnormity export module, connected to the resource detection module and configured to detect whether the resource detection module has detected the last item to-be-detected in the data table to-be-detected, the abnormity export module being configured to export the abnormity information table if the resource detection module has detected the last item to-be-detected.

A second aspect of the present disclosure provides an intelligent detection method, based on the semiconductor intelligent detection system according to the first aspect, comprising: providing a data table to-be-detected, the data table to-be-detected being input into the semiconductor intelligent detection system via the data import module; modifying the data table to-be-detected, based on the abnormity information table; and inputting the data table to-be-detected into the semiconductor intelligent detection system again until the semiconductor intelligent detection system cannot export the abnormity information table; and, storing the data table to-be-detected into the semiconductor intelligent detection system.

A third aspect of the present disclosure provides a computer-readable storage medium, having computer programs stored therein that, when executed by a processor, implement the semiconductor intelligent detection system according to the first aspect.

Other aspects will become apparent upon reading and understanding the drawings and detailed description.

### BRIEF DESCRIPTION OF THE DRAWINGS

The drawings incorporated into the specification and constituting a part of the specification show the embodiments of the present disclosure, and are used with the description to explain the principles of the embodiments of the present disclosure. Throughout the drawings, like reference numerals denote like elements. The drawings to be described hereinafter are some but not all of the embodiments of the present disclosure. Those skilled in the art can obtain other drawings according to these drawings without paying any creative effort.

FIGS. 1 and 2 are schematic structure diagrams of a semiconductor intelligent detection system according to an embodiment of the present disclosure;

FIGS. 3 and 4 are flowcharts of an intelligent detection method according to another embodiment of the present disclosure; and

FIGS. 5-8 are schematic diagrams of data tables in the detection flows according to another embodiment of the present disclosure.

### DETAILED DESCRIPTION

The technical solutions in the embodiments of the present disclosure will be described clearly and completely with reference to the drawings in the embodiments of the present disclosure. Apparently, the embodiments to be described are only some but not all of the embodiments of the present disclosure. All other embodiments obtained based on the embodiments in the present disclosure by those skilled in the art without paying any creative effort shall fall into the protection scope of the present disclosure. It is to be noted that the embodiments of the present disclosure and the features in the embodiments can be arbitrarily combined with each other if not conflicted.

At present, Flow resource setting errors will affect the subsequent process of a large number of wafers and thus have a fatal impact on the operation of the factory.

However, since one complete Flow resource contains too many sub-items, the time consumption of manual detection is large, and the accuracy of resources cannot be ensured completely. How to quickly and automatically detect the correctness of Flow resources is a technical problem to be urgently solved at present.

An embodiment of the present disclosure provides a method for forming a semiconductor structure, comprising: a data import module, configured to acquire a data table to-be-detected, there being a plurality of items to-be-detected in the data table to-be-detected, the items to-be-detected comprising multiple types of semiconductor process resources; a data storage module, having a process resource database stored therein, the data type of data stored in the process resource database being used to perform data detection on items to-be-detected of a corresponding type; a resource detection module, connected to the data import module and the data storage module; wherein the resource detection module is configured to perform data detection on the items to-be-detected in the data table to-be-detected one by one based on the data type of the data stored in the process resource database, and record wrong items to-be-detected in an abnormity information table; and, an abnormity export module, connected to the resource detection module and configured to detect whether the resource detection module has detected the last item to-be-detected in the data table to-be-detected, the abnormity export module being configured to export the abnormity information table if the resource detection module has detected the last item to-be-detected.

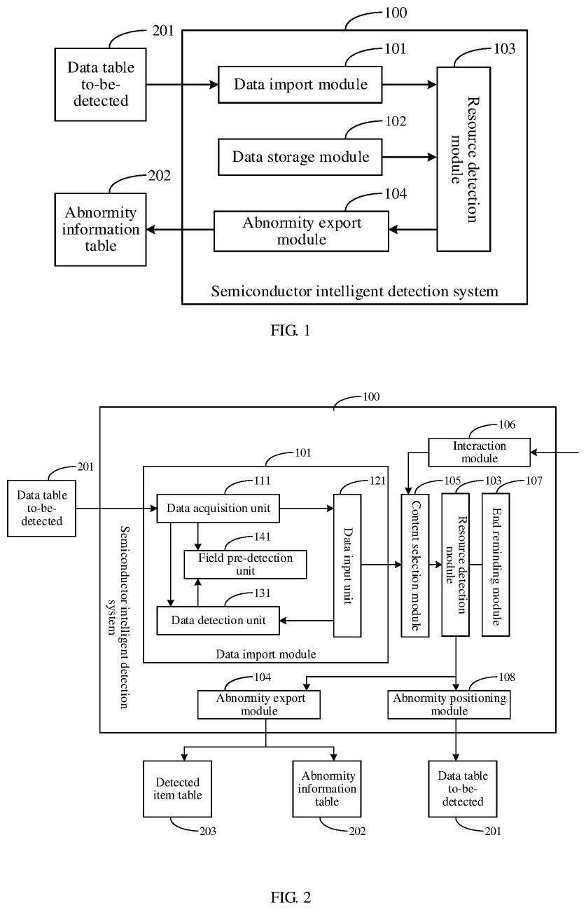

FIGS. 1 and 2 are schematic structure diagrams of the semiconductor intelligent detection system according to this embodiment. The semiconductor intelligent detection system according to this embodiment will be described in detail below with reference to the drawings.

Referring to FIG. 1, the semiconductor intelligent detection system 100 comprises:

a data import module 101, configured to acquire a data table to-be-detected 201, there being a plurality of items to-be-detected in the data table to-be-detected 201, the items to-be-detected comprising multiple types of semiconductor process resources.

In this embodiment, the multiple types of semiconductor process resources comprise: at least one of contamination level control, photo-resistance control, process sequence detection, station function, naming rule, called existing parameter, process specification, special character, process recipe usage logic and production control logic.

As for the semiconductor process resource about the contamination level control, in an example, if the carrier category of the wafer carrier box set by the station is Cu, the set contamination-in can only be set as copper. This detection can prevent wafers without copper ions being allowed by the system to be placed in the wafer carrier box carrying the carrier category and resulting in copper ion contamination of wafers.

As for the semiconductor process resource about the photo-resistance control, in an example, if the photo-resistance (PR) control set by the station is to set photo-resistance and if the department set by the station is not photo process (PH), an error will be reported. In the actual semiconductor process, only photo process stations can apply photoresist on wafers. This detection can prevent the system from wrongly carrying photo-resistance information on wafers due to the wrong setting of flow and resulting misjudgment caused by human beings or the system.

As for the semiconductor process resource about the process sequence detection, in an example, it is detected whether the station operation code and process stage code set by the station before and after detection are sorted from small to large, and it is determined whether there is a possibility of reverse processes in the settings, thereby avoiding wafer scrapping caused by reverse processes.

As for the semiconductor process resource about the station function, in an example, if the station sets a field related to the wafer sorter action, and if it is detected that the equipment used by the current station is not a wafer sorter, an error is reported, avoiding from causing abnormal execution of the system and delaying the production line process due to the failure of the online equipment in executing the operations set in the flow.

As for the semiconductor process resource about the naming rule, in an example, it is detected whether the ending code of the equipment recipe set by the station corresponds to the ending code of the available chamber. For example, if the recipe is named “XXX_ABC” while the set process chamber is “CHA, CHB”, an error is reported. By detecting whether the resource content meets the predefined naming rule, it can be convenient for data management, and the misjudgment caused by human beings or the system can be avoided.

As for the semiconductor process resource about the called existing parameter, in an example, it is detected whether the process chamber used by the station has been set in the equipment in the SM system, avoiding setting failure caused by the setter's inability to use relevant parameters during SM setting.

As for the semiconductor process resource about the process specification, in an example, if the control line range of the measurement result set by the station needs to be less than the specification line range, all wafers needs to enter the process station, and the sampling logic (LR sampling policy) cannot be set.

As for the semiconductor process resource about the special character, in an example, if “*” is included in the process recipe set by the station, “*” represents fuzzy search, so it is very likely to result in misjudgment of system or manual data search.

As for the semiconductor process resource about the process recipe usage logic (SM system logic), in an example, if the station is not set to use the process chamber, one equipment in this station cannot correspond to multiple process recipes, avoiding setting failure caused by the setter violating the setting rule during SM setting.

As for the semiconductor process resource about the production control logic (MM system logic), in an example, if the station sets the production control script as AutoGatePass, the field indicating whether this station must pass through the mandatory must be set as No; or otherwise, the online wafer cannot move due to the execution logic conflict, thereby delaying the production line process.

It is to be noted that, in the above description of the examples of different semiconductor process resources, the detection modes used by those skilled in the art to understand various types of semiconductor process resources do not constitute any limitations to this embodiment, that is, the detection mode for each type of resources include, but not limited to, the detection modes described by the above examples.

In an exemplary implementation, referring to FIG. 2, the data import module 101 comprises:

a data acquisition unit 111, configured to acquire the data table to-be-detected 201;

a data input unit 121, connected to the data acquisition unit 111 and configured to input the data table to-be-detected 201 acquired by the data acquisition unit 111; and

a data detection unit 131, connected to the data acquisition unit 111 and the data input unit 121 and configured to detect whether the data in the data table to-be-detected 201 inputted by the data input unit 121 is consistent with the data in the data table to-be-detected 201 acquired by the data acquisition unit 111. By detecting, by the data detection unit, the data inputted by the data input unit, the accuracy of the inputted data in the data table to-be-detected 201 is ensured.

It is to be noted that, in this embodiment, the data import module 101 further comprises: a field pre-detection unit 141, configured to pre-detect a field name in the data table to-be-detected 201; wherein the field name is set as the name representing the items to-be-detected of the same data type. Before the detection of the inputted data table to-be-detected, the field name in the data table to-be-detected is pre-detected to ensure the accuracy of detection. When an error occurs in the field name in the data table to-be-detected, a large amount of the resource detection time can be saved by firstly executing pre-detection. In this embodiment, by pre-detecting the field name in the data table to-be-detected, invalid detection of the items to-be-detected under the unrecognizable field name is avoided, and the efficiency and accuracy of detection of the data table to-be-detected are thus improved.

Continuously referring to FIG. 1, the semiconductor intelligent detection system 100 further comprises a data storage module 102, having a process resource database stored therein, the data type of data stored in the process resource database being used to perform data detection on items to-be-detected of a corresponding type. By detecting the items to-be-detected in the data table to-be-detected 201 by using correct data resources in the database, the accuracy of data detection is ensured.

The semiconductor intelligent detection system 100 further comprises: a resource detection module 103, connected to the data import module 101 and the data storage module 102; where the resource detection module is configured to perform data detection on the items to-be-detected in the data table to-be-detected 201 one by one based on the data type of the data stored in the process resource database, and record wrong items to-be-detected in an abnormity information table 202 (referring to FIG. 2).

In an example, referring to FIG. 2, the resource detection module 103 comprises a plurality of detection units, each of the detection units corresponds to one data type of the items to-be-detected, and the plurality of detection units are configured to perform classification detection on the items to-be-detected. By classifying the data types of the items to-be-detected in the data table to-be-detected 201 by using the detection units, one type of items to-be-detected is correspondingly detected by one or more detection units, so that the simultaneous detection of the items to-be-detected of different data types by different detection units is realized, and the efficiency of detection of the items to-be-detected in the data table to-be-detected 201 is improved.

In this embodiment, the semiconductor intelligent detection system 100 further comprises: a content selection module 105; wherein the data import module 101 is connected to the resource detection module 103 by the content selection module 105;

the content selection module 105 is configured to select a data type in the data table to-be-detected according to a control command, and input the items to-be-detected of the selected data type into the resource detection module 103. By selecting the data type of the items to-be-detected by using the content selection module, the targeted detection of the resource to-be-detected is realized.

In this embodiment, the semiconductor intelligent detection system 100 further comprises: an interaction module 106, connected to the content selection module 105 and configured to transmit, according to an external trigger instruction, the control command corresponding to the external trigger instruction to the content selection module 105.

By setting the content selection module 105 and the interaction module 106, the targeted detection of the specified data in the data table to-be-detected 201 is realized, and the selective detection of the data table to-be-detected 201 is thus realized. In an example, the setter select, by the interaction module 106, the data type of the items to-be-detected in the data table to-be-detected 201, and the interaction module 106 generates a control command corresponding to the data type according to the data type selected by the setter so as to control the resource detection module to detect the items to-be-detected of the specified data type in the data table to-be-detected 201.

Continuously referring to FIG. 1, the semiconductor intelligent detection system 100 further comprises: an abnormity export module 104, connected to the resource detection module 103 and configured to detect whether the resource detection module 103 has detected the last item to-be-detected in the data table to-be-detected 201; the abnormity export module 104 is configured to export the abnormity information table 202 if the resource detection module 103 has detected the last item to-be-detected (referring to FIG. 2). After the semiconductor intelligent detection system 100 has detected the data table to-be-detected 201, the abnormity information table 202 is exposed, wrong items to-be-detected are recorded in the abnormity information table 202, and the setter can modify the wrong item to-be-detected according to the abnormity information table 202.

In this embodiment, the resource detection module 103 is further configured to generate a detected item table 203 during the detection of the data table to-be-detected 201 (referring to FIG. 2); the detected item table 203 is configured to record abnormity information of the wrong items to-be-detected; and, if the resource detection module 203 has detected the last item to-be-detected, the abnormity export module 104 is further configured to export the detected item table 203. By recording the abnormity information of the items to-be-detected by using the detected item table, it is convenient for the resource applicant to modify Flow resources. After the semiconductor intelligent detection system 100 has detected the data table to-be-detected 201, the detected item table 203 is exported, wrong information of the wrong items to-be-detected is recorded in the detected item table 203, and the setter can modify the items to-be-detected according to the wrong information recorded in the detected item table 203 and in combination with the abnormity information table 202, so that the efficiency of modifying the data table to-be-detected 201 is improved.

It is to be noted to that, in this embodiment, the resource detection module 103 is further configured to record detected item information in the abnormity information table 202; the detected item information is configured to represent a detection rule of the resource detection module 103 for the data table to-be-detected 201. By exporting the detection rule of the resource detection module 103, it is convenient for the setter to modify the wrong items to-be-detected in the data table to-be-detected 201 according to the detection rule, thereby preventing the presence of errors in the data table to-be-detected 201.

In an exemplary implementation, the resource detection module 103 is further configured to generate a positioning array; the positioning array is configured to associate the position of the item to-be-detected corresponding to the detected item table 203 in the data table to-be-detected 201. By associating the wrong positions in the detected item table 203 and the data table to-be-detected 201 by using the positioning array, it is convenient for the setter to search and modify the wrong items to-be-detected.

On this basis, the abnormity export module 104 is further configured to export the detected item table 203 comprises: the abnormity export module 104 imports the abnormity information of the detected item table 203 into the data table to-be-detected 201 by the positioning array. By importing the abnormity information into the data table to-be-detected 201, the abnormity information is embodied at the wrong position in the data table to-be-detected 201, so that it is advantageous for the setter to modify the wrong items to-be-detected.

Referring to FIG. 2, in this embodiment, the semiconductor intelligent detection system 100 further comprises: an abnormity positioning module 108, connected to the resource detection module 103; the abnormity positioning module is configured to acquire the position of each wrong item to-be-detected in the abnormity information table 202 in the data table to-be-detected 201, and highlight the position of the wrong item to-be-detected in the data table to-be-detected 201. The abnormity positioning module 108 is further configured to export the highlighted data table to-be-detected 201. By highlighting the position of the wrong item to-be-detected in the data table to-be-detected 201, it is convenient for the setter to search the wrong item to-be-detected.

In an example, the highlighting mode comprises: displaying in bold the wrong item to-be-detected or marking the background color on the position where the wrong item to-be-detected is located. By highlighting the wrong position in the data table to-be-detected, the resource applicant can be prevented from missing to modify the wrong Flow resource.

In addition, referring to FIG. 2, in this embodiment, the semiconductor intelligent detection system 100 further comprises: an end reminding module 107 connected to the resource detection module 103; the end reminding module 107 is configured to give out reminding information if the resource detection module 103 has detected the last item to-be-detected. By giving out the reminding information to the setter by the end reminding module 107, the information already detected in the data table to-be-detected 201 quickens the modification and input of the data table to-be-detected by the setter, so that the detection efficiency of the data table to-be-detected is improved.

Compared with the prior art, by designing a semiconductor intelligent detection system, the detection process of the flow setter is replaced with machine detection, and the detection of Flow resources is completed rapidly and accurately. In addition, the semiconductor intelligent detection system outputs an abnormity information table after detecting the Flow resources. The abnormity information table is configured to record the wrong items to-be-detected, i.e., feedback wrong information to the Flow resource applicant. By directly controlling the semiconductor intelligent detection system by the Flow resource applicant, the tedious process of Flow resource detection and modification is simplified.

It is worth mentioning that the units involved in this embodiment are logic units. In practical applications, one logic unit may be a physical unit or a part of a physical unit, or may be implemented by a combination of a plurality of physical units. In addition, in order to highlight the innovative part of the present disclosure, the units that are not closely related to solving the technical problem provided by the present disclosure are not introduced in this embodiment, but it does not mean that there are no other units in this embodiment.

Another aspect of the present disclosure provides an intelligent detection method, which is based on the semiconductor intelligent detection system provided in the above embodiment, comprising following steps: providing a data table to-be-detected, the data table to-be-detected being input into the semiconductor intelligent detection system via the data import module; modifying the data table to-be-detected based on the abnormity information table, and inputting the data table to-be-detected into the semiconductor intelligent detection system again until the semiconductor intelligent detection system cannot export the abnormity information table; and, storing the data table to-be-detected into the semiconductor intelligent detection system.

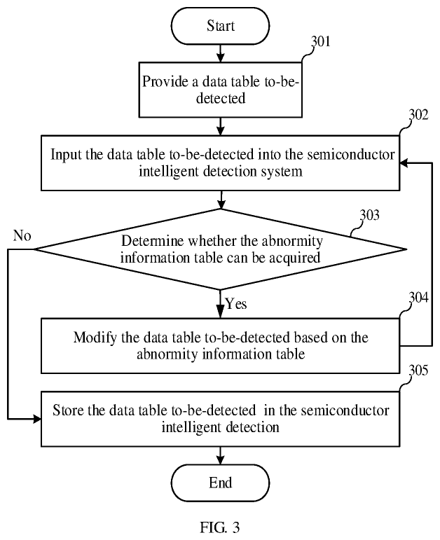

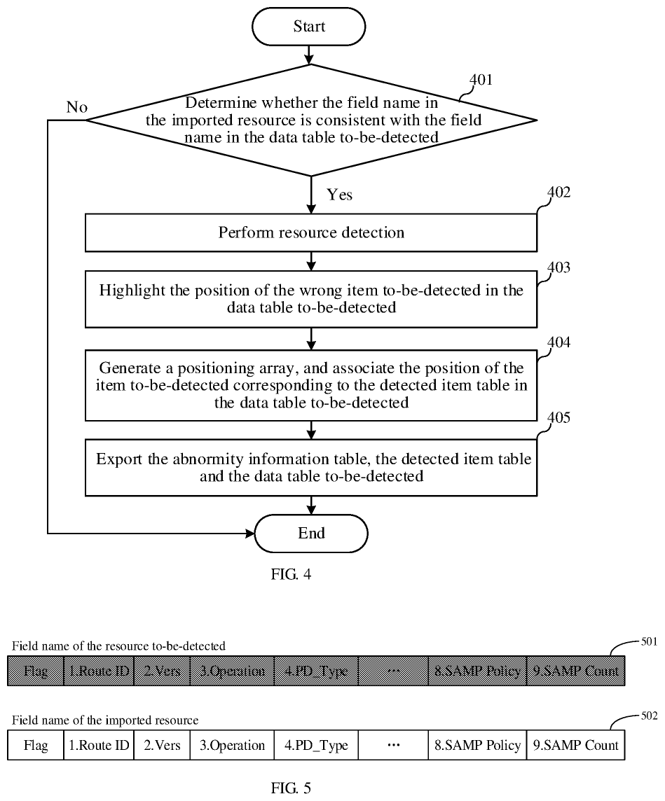

FIGS. 3 and 4 are flowcharts of the intelligent detection method according to this embodiment, and FIGS. 5-8 are schematic diagrams of data tables in the detection flows according to this embodiment. The intelligent detection method according to this embodiment will be described in detail below with reference to the drawings, and the same or corresponding parts corresponding to the above embodiment will not be repeated hereinafter.

Referring to FIG. 3, the intelligent detection method comprises the following steps.

Step 301: A data table to-be-detected is provided.

Step 302: The data table to-be-detected is inputted into the semiconductor intelligent detection system.

The setter imports the acquired data table to-be-detected into the semiconductor intelligent detection system via the data import module. In an example, the importing mode comprises importing by scanning or importing by inputting. It is to be noted that, in specific applications, the data importing mode can be selected according to the amount of data in the data table to-be-detected, and this embodiment does not constitute any limitations to the mode of importing data into the semiconductor intelligent detection system.

Step 303: It is determined whether an abnormity information table can be acquired. If the abnormity information table cannot be acquired, it is indicated that there is no error in the data table to-be-detected, and step 305 will be executed; and, if the abnormity information table is acquired, it is indicated that there is an error in the data table to-be-detected, and step 304 will be executed.

In an exemplary implementation, referring to the drawings, step 303 comprises the following steps.

Step 401: It is determined whether the field name of the imported resources is consistent with the field name in the data table to-be-detected.

In an exemplary implementation, referring to FIG. 5, during the execution of the data import, the semiconductor intelligent detection system will perform control detection from the first field name to the last field name in the imported information to determine whether the imported field module name 502 is consistent with the field name 501 in the data table to-be-detected. If the imported field module name 502 is not consistent with the field name 501 in the data table to-be-detected, a corresponding abnormity information table is output for error reporting. In this case, the setter needs to modify the field format and import the resource again. If the field name is correct, the subsequent resource detection will be executed, that is, step 402 will be executed.

S402: Resource detection is performed.

In an exemplary implementation, the items to-be-detected in the data table to-be-detected are detected one by one based on the data type of data stored in the process resource database, and wrong items to-be-detected are recorded in the abnormity information table.

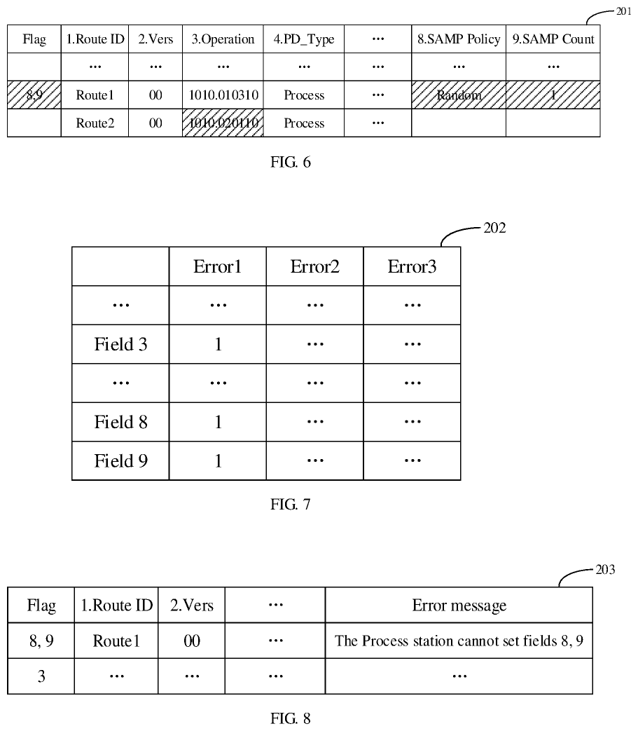

In an example, referring to FIG. 6, the items to-be-detected are detected line by line, and the resources of the items to-be-detected in all columns are detected according to different rules such as production flow route, process station (Operation) and process station sub-item.

SS403: The positions of the wrong items to-be-detected in the data table to-be-detected are continuously highlighted.

Continuously referring to FIG. 6, if it is detected that an abnormity occurs in an item to-be-detected in the resources to-be-detected, the corresponding item to-be-detected in the resource to-be-detected is highlighted. In this embodiment, the highlighting mode is marking the field where the item to-be-detected is located, and indicating a wrong field code in an abnormity row for convenience of searching.

Step 404: A positioning array is generated to associate the position of the item to-be-detected corresponding to the detected item table in the data table to-be-detected.

A two-dimensional array (the row code corresponds to the field number, and the column code corresponds the field error item) to temporarily store error serial numbers, for example, AR (storing Route error information), AO (storing Operation error information), AS (storing Sub item error information), etc.

Referring to FIG. 7, during the continuous detection of the data table to-be-detected, the abnormity information of the wrong item to-be-detected is recorded in the detected item table 203 (referring to FIG. 7), where the row corresponds to the resource field number, the column corresponds to the abnormity code, and the table content is the content of the abnormity information. Each field in the detected item table 203 corresponds to the data table to-be-detected 201 by the two-dimensional array. If the value corresponding to a certain row and a certain column in the array is 1, the row content of the resource to-be-detected that is detected currently outputs production flow route, production process station (Operation) and production process station sub-item to the abnormity information table 202 (referring to FIG. 8), the abnormity information of the abnormity field is searched based on the row number and column number corresponding to the value of 1 in the two-dimensional array to the detected item table 203, and the abnormity information is imported into the corresponding position in the abnormity information table 202.

Step 405: The abnormity information table 202, the detected item table 203 and the data table to-be-detected 201 are exported.

In an exemplary implementation, after the last item to-be-detected in the data table to-be-detected has been detected, the data table to-be-detected 201 (referring to FIG. 8), the detected item table 203 (referring to FIG. 7) and the abnormity information table 202 (referring FIG. 8) are exported.

Step 304: The data table to-be-detected is modified based on the abnormity information. After step 304 is executed, the data table to-be-detected is inputted into the semiconductor intelligent detection system for secondary selection, that is, step 302 is continuously executed, until there is no error in the data table to-be-detected.

In an exemplary implementation, the data table to-be-detected is modified based on the abnormity information, and the data table to-be-detected is imputed into the semiconductor intelligent detection system again until the semiconductor intelligent detection system cannot export the abnormity information table.

Step 305: The data table to-be-detected is stored in the semiconductor intelligent detection system.

Compared with the prior art, by replacing the detection process of the flow setter with machine detection, the detection of Flow resources is completed rapidly and accurately. In addition, the semiconductor intelligent detection system outputs an abnormity information table after detecting the Flow resources. The abnormity information table is configured to record the wrong items to-be-detected, i.e., feedback wrong information to the Flow resource applicant. By directly controlling the semiconductor intelligent detection system by the Flow resource applicant, the tedious process of Flow resource detection and modification is simplified.

Various embodiments or implementations in this specification have been described progressively, and each embodiment focuses on the differences from other embodiments, so the same and similar parts of the embodiments may refer to each other.

In the description of this specification, the description with reference to terms “an embodiment”, “an exemplary embodiment”, “some embodiments”, “an illustrative implementation” or “an example” means that specific features, structures, materials or characteristics described with reference to an implementation or example are included in at least one implementation or example of the present disclosure.

In this specification, the schematic expressions of the terms do not necessarily refer to the same implementation or example. In addition, the described specific features, structures, materials or characteristics may be combined in any one or more implementations or examples in a proper way.

In the description of the present disclosure, it should be understood that the orientation or position relationship indicated by terms “center”, “upper”, “lower”, “left”, “right”, “vertical”, “horizontal”, “inner”, “outer” and the like is an orientation or position relationship illustrated based on the drawings, and is only for describing the present disclosure and simplifying the description, rather than indicating or implying that the specified device or element must have a particular direction and be constructed and operated in a particular direction. Therefore, the terms cannot be interpreted as limitations to the present disclosure.

It should be understood that the terms such as “first” and “second” used in the present disclosure can be used in the present disclosure to describe various structures, but these structures are not limited by these terms. The terms are only used to distinguish a first structure from another structure.

Throughout one or more drawings, the same elements are denoted by similar reference numerals. For clarity, many parts in the drawings are drawn to scale. In addition, some known parts may not be shown. For simplicity, the structures obtained after several steps can be described in one drawing. Many specific details of the present disclosure are described hereinafter, for example, the structures, materials, sizes, processing processes and technologies of the devices, in order to understand the present disclosure more clearly. As will be understood by those skilled in the art, the present disclosure may be implemented without these specific details.

Finally, it is to be noted that the foregoing embodiments are only used for describing the technical solutions of the present disclosure, rather than limiting the present disclosure. Although the present disclosure has been described in detail by the foregoing embodiments, a person of ordinary skill in the art should understood that modifications can still be made to the technical solutions recorded in the foregoing embodiments or equipment replacements can be made to some or all of the technical features, and these modifications or replacements do not make the essence of the corresponding technical solutions depart from the scope of the technical solutions in the embodiments of the present disclosure.

### INDUSTRIAL APPLICABILITY

In the semiconductor intelligent detection system, the intelligent detection method and the storage medium according to the embodiments of the present disclosure, by replacing the detection process of the flow setter with machine detection, the detection of Flow resources is completed rapidly and accurately. In addition, the semiconductor intelligent detection system outputs an abnormity information table after detecting the Flow resources. The abnormity information table is configured to record the wrong items to-be-detected, i.e., feedback wrong information to the Flow resource applicant. By directly controlling the semiconductor intelligent detection system by the Flow resource applicant, the tedious process of Flow resource detection and modification is simplified.

1. A semiconductor intelligent detection system, comprising:
a data import module, configured to acquire a data table to-be-detected, there being a plurality of items to-be-detected in the data table to-be-detected, the items to-be-detected comprising multiple types of semiconductor process resources;
a data storage module, having a process resource database stored therein, a data type of data stored in the process resource database being used to perform data detection on items to-be-detected of a corresponding type;
a resource detection module, connected to the data import module and the data storage module; wherein the resource detection module is configured to perform data detection on items to-be-detected in the data table to-be-detected one by one based on the data type of the data stored in the process resource database, and record wrong items to-be-detected in an abnormity information table; and
an abnormity export module, connected to the resource detection module and configured to detect whether the resource detection module has detected the last item to-be-detected in the data table to-be-detected, the abnormity export module being configured to export the abnormity information table if the resource detection module has detected the last item to-be-detected.

2. The semiconductor intelligent detection system according to claim 1, wherein the data import module comprises:
a data acquisition unit, configured to acquire the data table to-be-detected;
a data input unit, connected to the data acquisition unit and configured to input the data table to-be-detected acquired by the data acquisition unit; and
a data detection unit, connected to the data acquisition unit and the data input unit, and configured to detect whether a data in the data table to-be-detected inputted by the data input unit is consistent with a data in the data table to-be-detected acquired by the data acquisition unit.

3. The semiconductor intelligent detection system according to claim 1, wherein the data import module further comprises: a field pre-detection unit, configured to pre-detect a field name in the data table to-be-detected; wherein the field name is set as a name representing items to-be-detected of the same data type.

4. The semiconductor intelligent detection system according to claim 1, wherein the resource detection module comprises a plurality of detection units, each of the detection units corresponds to one data type of the items to-be-detected, and the plurality of detection units are configured to perform classification detection on the items to-be-detected.

5. The semiconductor intelligent detection system according to claim 1, wherein the multiple types of semiconductor process resources comprise: at least one of contamination level control, photo-resistance control, process sequence detection, station function, naming rule, called existing parameter, process specification, special character, process recipe usage logic and production control logic.

6. The semiconductor intelligent detection system according to claim 1, further comprising: a content selection module; wherein the data import module is connected to the resource detection module by the content selection module; the content selection module is configured to select a data type in the data table to-be-detected according to a control command, and input the items to-be-detected of a selected data type into the resource detection module.

7. The semiconductor intelligent detection system according to claim 6, further comprising: an interaction module, connected to the content selection module;
wherein the interaction module is configured to transmit, according to an external trigger instruction, the control command corresponding to the external trigger instruction to the content selection module.

8. The semiconductor intelligent detection system according to claim 1, wherein the resource detection module is further configured to generate a detected item table during the detection of the data table to-be-detected; the detected item table is configured to record abnormity information of wrong items to-be-detected; and
if the resource detection module has detected the last item to-be-detected, the abnormity export module is further configured to export the detected item table.

9. The semiconductor intelligent detection system according to claim 8, wherein the resource detection module is further configured to generate a positioning array; the positioning array is configured to associate a position of the item to-be-detected corresponding to the detected item table in the data table to-be-detected.

10. The semiconductor intelligent detection system according to claim 9, wherein the abnormity export module is further configured to export the detected item table comprises: the abnormity export module imports the abnormity information of the detected item table into the data table to-be-detected by the positioning array.

11. The semiconductor intelligent detection system according to claim 1, further comprising: an abnormity positioning module, connected to the resource detection module;
wherein the abnormity positioning module is configured to acquire a position of each wrong item to-be-detected in the abnormity information table in the data table to-be-detected, and highlight the position of the wrong item to-be-detected in the data table to-be-detected; and
the abnormity positioning module is further configured to export a highlighted data table to-be-detected.

12. The semiconductor intelligent detection system according to claim 11, wherein a highlighting mode comprises: displaying in bold the wrong item to-be-detected or marking a background color on a position where the wrong item to-be-detected is located.

13. The semiconductor intelligent detection system according to claim 1, wherein the resource detection module is further configured to record detected item information in the abnormity information table; the detected item information is configured to represent a detection rule of the resource detection module for the data table to-be-detected.

14. The semiconductor intelligent detection system according to claim 1, further comprising: an end reminding module, connected to the resource detection module;
wherein the end reminding module is configured to give out reminding information if the resource detection module has detected the last item to-be-detected.

15. An intelligent detection method, based on the semiconductor intelligent detection system according to claim 1, comprising:
providing a data table to-be-detected, the data table to-be-detected being input into the semiconductor intelligent detection system via the data import module;
modifying the data table to-be-detected, based on the abnormity information table; and inputting the data table to-be-detected into the semiconductor intelligent detection system again until the semiconductor intelligent detection system cannot export the abnormity information table; and
storing the data table to-be-detected into the semiconductor intelligent detection system.

16. A computer-readable storage medium, having computer programs stored therein that, when executed by a processor, implement the semiconductor intelligent detection system according to claim 1.
